(19) United States
(12) Patent Application Publication
(10) Pub. No.: US 2012/0205810 A1
(43) Pub. Date: Aug. 16, 2012

(54) SEMICONDUCTOR DEVICE AND FABRICATING METHOD THEREOF

(75) Inventor: Tai Ho KIM, Seongnam-si (KR)

(73) Assignee: HYNIX SEMICONDUCTOR INC., Icheon-si (KR)

(21) Appl. No.: 13/365,436

(22) Filed: Feb. 3, 2012

(30) Foreign Application Priority Data
Feb. 15, 2011 (KR) 10-2011-0013474

(51) Int. Cl. H01L 21/768; H01L 23/48

(52) U.S. Cl. 257/773; 438/666; 257/E23.01; 257/E21.581

(57) ABSTRACT

A method for fabricating a semiconductor device includes forming an interlayer dielectric layer including contact holes on a semiconductor substrate, forming contact patterns by filling the contact holes with a conductive material, removing the interlayer dielectric layer to expose the contact patterns, forming a spacer which has a first thickness and surrounds at least a portion of sidewalls of the contact patterns, forming a bit line extending in one direction of the contact pattern provided with the spacer, and removing the spacer to form an air gap in between the contact pattern and the bit line.

### CROSS-REFERENCES TO RELATED APPLICATIONS

The present application claims priority under 35 U.S.C 119(a) to Korean Application No. 10-2011-0013474, filed on Feb. 15, 2011, in the Korean intellectual property Office, which is incorporated herein by reference in its entirety.

### BACKGROUND

Exemplary embodiments of the present invention relate generally to semiconductor device fabrication, and more particularly to a semiconductor device and a fabricating method thereof.

With broadening uses of mobile appliances and continued miniaturization thereof, the efforts to highly integrate the semiconductor devices constituting the mobile appliances or the digital home appliances continue. In the case of a dynamic random access memory (DRAM) device or a flash memory device, various attempts have been made in order to store a large quantity of information in a limited space. In general, a DRAM device includes a transistor and a capacitor, and has a stack structure in which the transistor is formed on a semiconductor substrate and the capacitor is formed thereon.

For an electrical connection between the transistor and the capacitor, storage node contacts are arranged between a source region of the transistor and a storage node electrode of the capacitor. Furthermore, a drain region of the transistor is electrically connected to a bit line through a bit line contact. As described above, in the structure in which the capacitor is arranged on the transistor, since signal transmission lines such as word lines or bit lines are arranged between the transistor and the capacitor, there is a limitation in increasing the capacity of the capacitor due to spaces occupied by the signal transmission lines. Moreover, storage node contacts have a large size so that the storage node contacts are connected to the storage node electrode. Since the bit line should be patterned to be arranged between the storage node contacts, a patterning process is complicated. In addition, a mask overlay may cause difficulty while patterning the bit line to be arranged between the storage node contacts. Therefore, various methods for patterning the storage node contacts, and etching the storage node contacts in an etch process for forming the bit line are being developed. However, in the etch process for forming the bit line according to a known art, oxide and metal layers should be simultaneously etched.

### SUMMARY

An embodiment of the present invention relates to a semiconductor device capable of solving a problem that it is necessary to simultaneously etch oxide and a metal layer in an etch process for forming a bit line and it is more difficult to pattern the bit line to be arranged between storage node contacts due to mask overlay, by introducing a method for forming the bit line without using a mask, and a fabricating method thereof.

In an embodiment, a method for fabricating a semiconductor device includes: forming an interlayer dielectric layer including contact holes on a semiconductor substrate; forming contact patterns by filling the contact holes with a conductive material; removing the interlayer dielectric layer to expose the contact patterns; forming a spacer which has a first thickness and surrounds sidewalls of the contact patterns; forming a bit line extending in one direction of the contact pattern provided with the spacer; and removing the spacer to form an air gap, in which a space of a first distance is arranged, between the contact pattern and the bit line.

In the embodiment, the contact holes may be arranged in a row in a first direction of the semiconductor substrate while being spaced apart from each other by a first space, and may be arranged in a second direction intersecting the first direction of the semiconductor substrate while being spaced apart from each other by a second space narrower than the first space.

Preferably, the first space is formed to have a width which is wider than a sum of a width of the bit line and a width of the spacer with a first thickness, and the second space is formed to have a width which is not larger than the width of the spacer which has a first thickness and surrounds the sidewalls of the contact patterns arranged in the second direction of the semiconductor substrate.

Preferably, the contact pattern includes a material having etching selectivity different from etching selectivity of a material constituting the interlayer dielectric layer.

The interlayer dielectric layer may be removed using a wet etch solution including a buffered oxide etchant (BOE) solution or a HF solution through a dip out process.

Preferably, the spacer includes a material having etching selectivity different from etching selectivity of a material constituting the contact pattern, and fills the second space between the contact patterns arranged in a first direction of the semiconductor substrate.

Preferably, the bit line surrounds at least ⅓ of the sidewalls of the contact patterns.

Preferably, the method further, after the forming of the bit line, includes: recessing the bit line by a first thickness from a surface of the bit line, thereby exposing a part of the spacer surrounding the contact pattern; and forming a nitride layer covering the bit line by the recessed first thickness.

Preferably, the method, further, after the forming of the air gap, includes: forming an etch stop layer including a nitride layer on the contact patterns, the bit line, and the air gap.

The etch stop layer may be formed only in an inlet of the air gap.

The spacer may be removed using a wet etch solution including a buffered oxide etchant (BOE) solution or a HF solution.

In another embodiment, a method for fabricating a semiconductor device includes: forming an interlayer dielectric layer on a semiconductor substrate, which includes contact holes arranged in a first direction of the semiconductor substrate while being spaced apart from each other by a first space, and arranged in a second direction perpendicular to the first direction of the semiconductor substrate while being spaced apart from each other by a second space narrower than the first space; forming contact patterns by filling the contact holes with a conductive material; removing the interlayer dielectric layer to expose the contact patterns; forming spacers which surround sidewalls of the contact patterns and fill the second space in the second direction; forming bit lines which go across in a row between the spacers; removing the spacer to form an air gap between the contact pattern and the bit line; and forming an etch stop layer on the contact patterns, the bit line, and the air gap.

In another embodiment, a semiconductor device includes: a semiconductor substrate; first contact patterns arranged in one direction of the semiconductor substrate while being spaced apart from each other by a first distance; second contact patterns arranged in parallel to the first contact patterns while being spaced apart from the first contact patterns by a second distance longer than the first distance; a bit line surrounds a part of the sidewalls of the first contact patterns or the second contact patterns while going across between the first contact patterns and the second contact patterns, which are spaced apart from each other by the second distance; an air gap arranged between the first contact patterns or the second contact patterns and the bit line; and an etch stop layer formed on the contact patterns, the bit line, and the air gap.

### BRIEF DESCRIPTION OF THE DRAWINGS

The above and other aspects, features and other advantages will be more clearly understood from the following detailed description taken in conjunction with the accompanying drawings, in which:

FIGS. 1 to 20 are diagrams explaining a method for fabricating a semiconductor device according to an embodiment of the present invention; and

FIG. 21 is a diagram explaining a semiconductor device according to an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

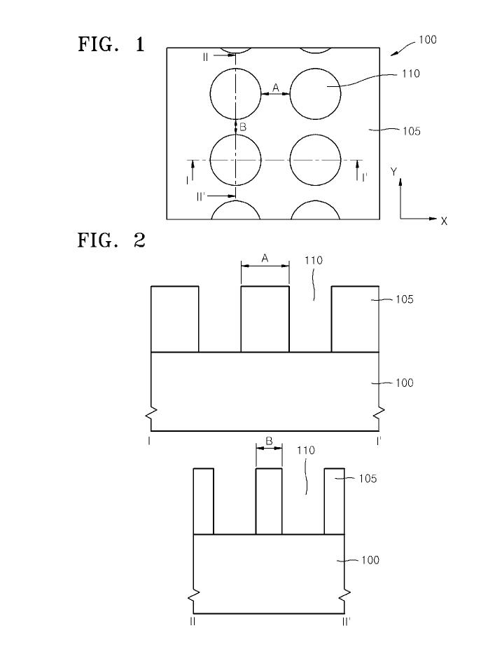

FIGS. 1 to 20 are diagrams explaining a method for fabricating a semiconductor device according to an embodiment of the present invention.

Referring to FIGS. 1 and 2, contact holes 110 are formed in an interlayer dielectric layer 105 formed on a semiconductor substrate 100. FIG. 2 is a sectional view of a part of FIG. 1, which is taken along the direction I-I′ or II-II′ of the semiconductor substrate 100. The interlayer dielectric layer 105 is formed on the semiconductor substrate 100. The interlayer dielectric layer 105 may be formed of oxide. In this case, although not shown in the drawings, word lines have been formed on the semiconductor substrate 100. The interlayer dielectric layer 105 is etched to form a plurality of contact holes 110. The contact holes 110 are arranged in a row in the X axis direction of the semiconductor substrate 100 while being spaced apart from each other by a first space A, and are arranged in a row in the Y axis direction intersecting the X axis direction of the semiconductor substrate 100 while being spaced apart from each other by a second space B narrower than the first space A. A space between the contact holes 110 including the first space A is an area where a bit line is to be formed later. Therefore, the first space A is formed to be wider than a sum of a width of the bit line to be formed later and a width of a spacer to be arranged at both sides of the bit line. Furthermore, the second space B is formed to have a width twice or less as wide as the width of the spacer to be formed later in order to prevent bit lines to be arranged adjacent to each other from being connected to each other. For example, when the bit line is formed to have a width of 100 Å and the spacer is formed to have a width of 50 Å, the width of the first space A may be wider than at least 200 Å and the width of the second space B may be narrower than at least 100 Å.

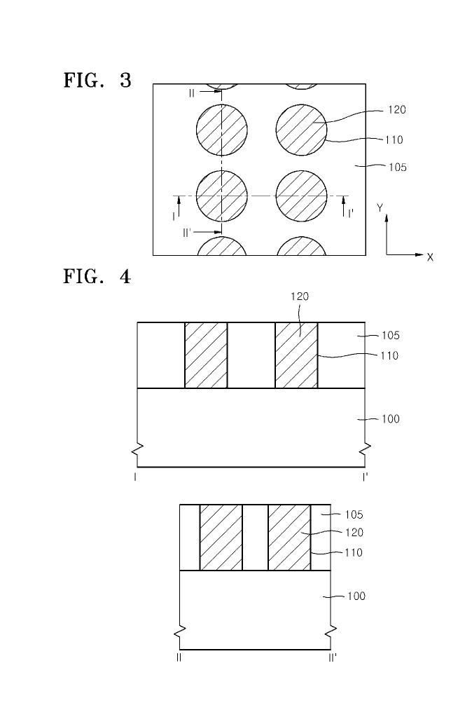

Referring to FIG. 3 and FIG. 4, the contact holes 110 are filled with a conductive material to form contact patterns 120. The conductive material is formed on the interlayer dielectric layer 105 and the contact holes 110 such that the conductive material is filled in the contact holes 110. The conductive material may be a material having selectivity with respect to oxide constituting the interlayer dielectric layer 105, and for example, may use a metal layer including titanium nitride TiN or polysilicon. A planarization process is performed to remove the conductive material on the interlayer dielectric layer 105, thereby forming the contact patterns 120 filled in the contact holes 110. The planarization process may be performed through an etch back process or a chemical mechanical polishing (CMP) process. The contact patterns 120 connect the storage node electrode, which is a bottom electrode of the capacitor, to a source region (not illustrated) on the semiconductor substrate 100.

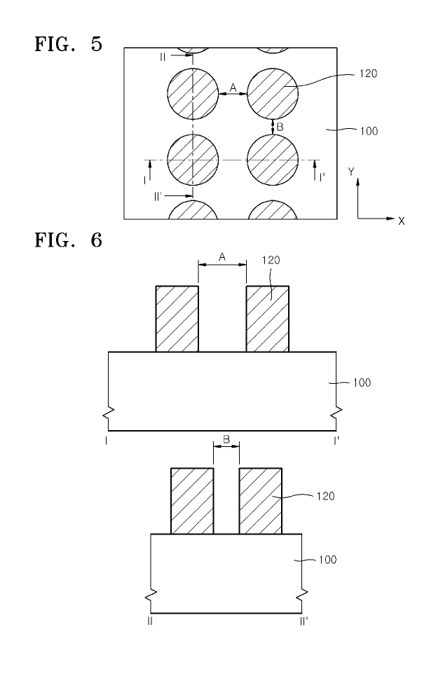

Referring to FIG. 5 and FIG. 6, the interlayer dielectric layer 105 is removed to expose both sides and upper surface of the contact patterns 120. Since the interlayer dielectric layer 105 is formed of oxide, the interlayer dielectric layer 105 may be removed using an etch method for removing oxide. Furthermore, the interlayer dielectric layer 105 may be removed using a wet etch solution including a buffered oxide etchant (BOE) solution or a HF solution through a dip out process. Accordingly, the contact patterns 120 are arranged in a row in the X axis direction of the semiconductor substrate 100 while being spaced apart from each other by the first space A, and are arranged in a row in the Y axis direction intersecting the X axis direction of the semiconductor substrate 100 while being spaced apart from each other by the second space B narrower than the first space A. The first space A is formed to be wider than a sum of a width of the bit line to be formed later and a width of the spacer to be arranged at both sides of the contact pattern 120, and the second space B is formed to have a width twice or less as wide as the width of the spacer to be formed later in order to prevent the bit lines to be arranged adjacent to each other from being connected to each other.

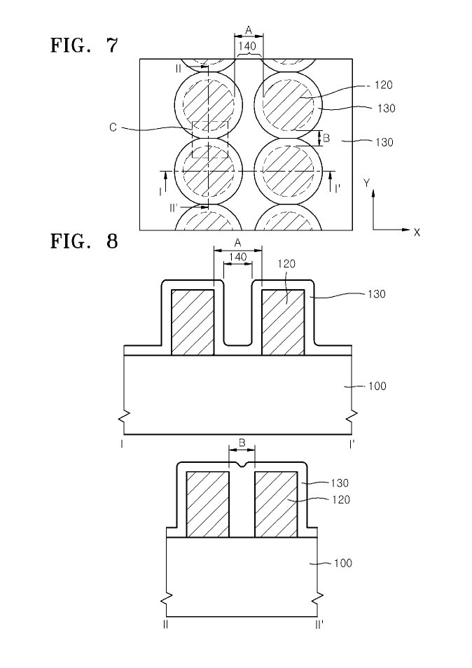

Referring to FIG. 7 and FIG. 8, a spacer material layer 130 is formed on the semiconductor substrate 100 including the contact pattern 120 having the exposed both sides and upper surface. The spacer material layer 130 may be formed of a material having etching selectivity different from that of a material constituting the contact pattern 120, and may include oxide. The first space A is arranged between the contact patterns 120 in the X axis direction of the semiconductor substrate 100, and the second space B narrower than the width of the first space A is arranged in the Y axis direction of the semiconductor substrate 100. Thus, the spacer material layer 130 is formed on the contact patterns 120, so that a space 140 where the bit line is to be formed remains in the first space A between the contact patterns 120 arranged in a row in the X axis direction of the semiconductor substrate 100, and the second space B between the contact patterns 120 arranged in a row in the Y axis direction of the semiconductor substrate 100 is filled with the spacer material layer 130 indicated by reference numeral ‘C’ of FIG. 7.

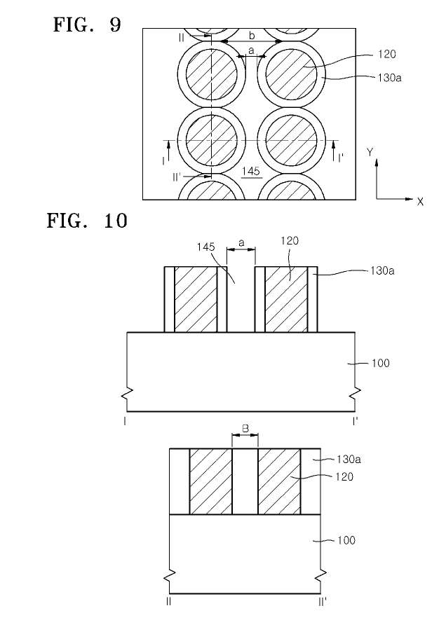

Referring to FIG. 9 and FIG. 10, a polishing process is performed on the spacer material layer 130 to form a spacer 130a exposing the upper surface of the contact pattern 120. The polishing process may be performed using an etch back process. The spacer material covering the upper surface of the contact pattern 120 is removed through the polishing process, so that the spacer 130a is formed to surround both sides of the contact pattern 120. Here, the spacer 130a, which fills the second space B between the contact patterns 120 arranged in the Y axis direction of the semiconductor substrate 100, remains without being removed in the etch back process. In this case, a space exposed between the contact patterns 120 is defined as a bit line contact hole 145 in which the bit line is to be formed later. The bit line contact hole 145 defined by the space exposed between the contact patterns 120 has a first width a exposed between the spacers 130a on the side surfaces of the contact patterns 120, and a second width b between the spacers 130 filling the second space B. In this case, since the second width b is arranged to be wider than the first width a, the bit line contact hole 145 has a curved line shape.

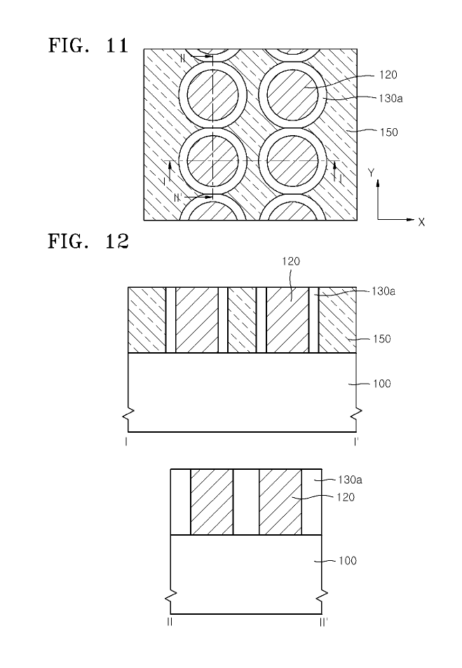

Referring to FIG. 11 and FIG. 12, a bit line 150 having a curved line shape is formed between the contact patterns 120. The bit line 150 may be formed by forming a conductive material on the semiconductor substrate 100 including the bit line contact hole (140, refer to FIG. 9) and performing a planarization process. The planarization process may be stopped when the upper surfaces of the contact pattern 120 and the spacer 130a are exposed. The planarization process may be performed using a CMP process. In this case, the conductive material constituting the bit line 150 may be formed of a material having etching selectivity different from that of a material constituting the contact pattern 120. For example, when the contact pattern 120 is formed of polysilicon, the bit line 150 may be formed of a metal material including titanium material TiN or tungsten W. When the contact pattern 120 is formed of titanium material TiN, the bit line 150 may be formed of tungsten W. Furthermore, when the contact pattern 120 is formed of tungsten W, the bit line 150 may be formed of titanium material TiN. The bit line 150 is formed to surround at least a portion of the spacer 130a that surrounds the sidewalls of the contact pattern. For example, the bit line 150 is formed to surround at least ⅓ of the spacer 130a.

In this case, the line width of the bit line 150 may be controlled by adjusting the deposition thickness of the spacer 130a. For example, when the first space A is formed to have a width of 200 Å and the bit line 150 is formed to have a line width of 100 Å, the spacer 130a is formed to have a thickness of 50 Å, thereby ensuring the line width of the bit line 150. For example, when the bit line 150 is formed to have a line width larger than 100 Å, the thickness of the spacer 130a is adjusted to be thinner than 50 Å, when the bit line 150 is formed to have a line width smaller than 100 Å, the thickness of the spacer 130a is adjusted to be thicker than 50 Å, thereby ensuring the line width of the bit line. Consequently, the uniformity of the line width of the bit line increases as compared with a method for forming a bit line using an etch process.

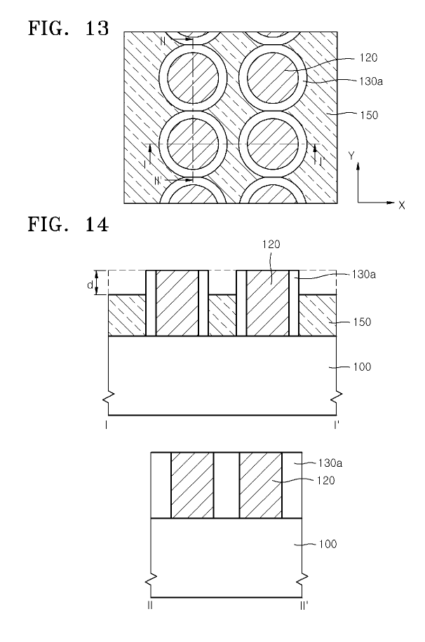

Referring to FIG. 13 and FIG. 14, the bit line 150 is recessed by a first height d to expose a portion of the spacer 130a surrounding the side surfaces of the contact pattern 120. A process for recessing the bit line 150 by the first height d may be performed using an etch back process. Since the spacer 130a and the contact pattern 120 are formed of a material having etching selectivity different from that of a material constituting the bit line 150, the spacer 130a and the contact pattern 120 are not removed in the etch back process, so that the spacer 130a surrounding the side surfaces of the contact pattern 120 is exposed by the recessed first height d.

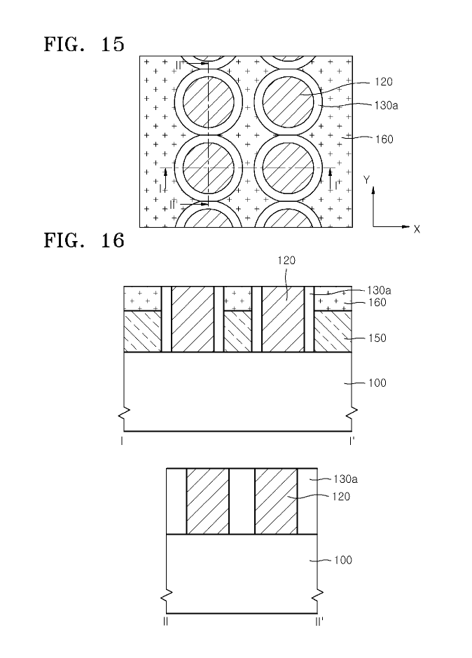

Referring to FIG. 15 and FIG. 16, a capping insulation layer 160 is formed on an exposed surface of the bit line 150 to cover the exposed surface of the bit line 150. The capping insulation layer 160 may be formed of nitride. The capping insulation layer 160 may be formed to have a thickness capable of covering the spacer 130a exposed by the first height d in the etch back process.

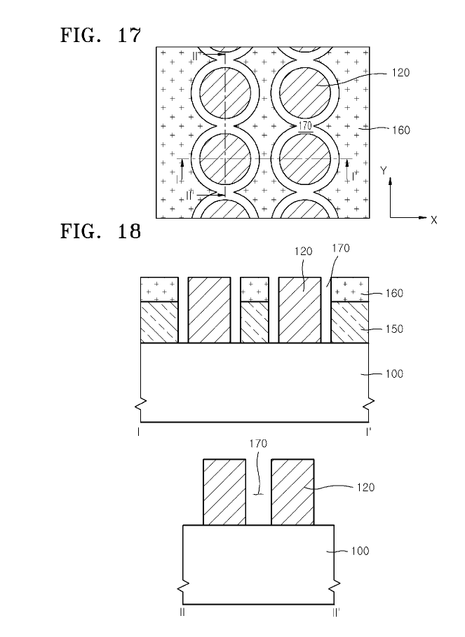

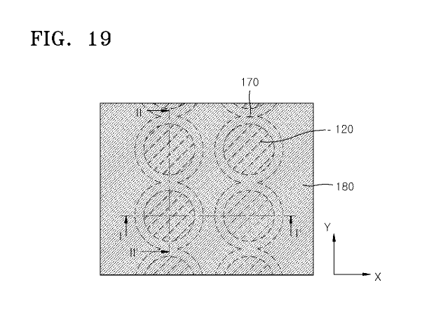

Referring to FIG. 17 and FIG. 18, the spacer 130a surrounding the contact pattern 120 is removed to expose the surface of the contact pattern 120. Since the spacer 130a is formed of oxide, the spacer 130a may be removed using an etch method for removing oxide. Furthermore, the spacer 130a may be removed using a wet etch solution including a buffered oxide etchant (BOE) solution or a HF solution through a dip out process. The spacer 130a is removed, so that an empty space is arranged between the contact pattern 120 and the bit line 150. Here, the empty space is defined as an air gap 170 for separating the contact pattern 120 from the bit line 150 as illustrated in FIG. 17.

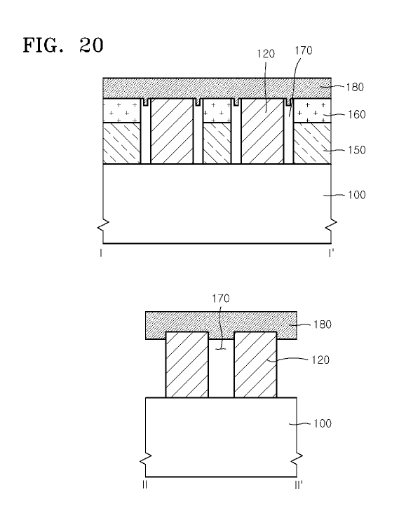

Referring to FIG. 19 and FIG. 20, an etch stop layer 180 is formed on the bit line 150 and the contact pattern 120. The etch stop layer 180 separates the storage node electrode, which is to be connected to the contact pattern 120, from the bit line 150. The etch stop layer 180 may be formed of an insulation material having etching selectivity different from that of the contact pattern 120. In an embodiment of the present invention, as the contact pattern 120 is formed of polysilicon or a metal material, the etch stop layer 180 may be formed of a material (e.g., nitride) having etching selectivity different from that of the polysilicon or the metal material. Since the etch stop layer 180 is formed on the bit line 150 and the contact pattern 120, the etch stop layer 180 is also formed on the air gap 170. However, since the air gap 170 has a narrow width corresponding to the thickness of the spacer 130a, the etch stop layer 180 is formed, for example, only in an inlet of the air gap 170. The interlayer dielectric layer formed of a dielectric material and a bit line spacer may ne arranged between a bit line and a contact pattern. However, in an embodiment of the present invention, the air gap 170 is formed between the bit line 150 and the contact pattern 120 instead of a dielectric material, and thus parasitic capacitance between a bit line and a storage node electrode may decrease.

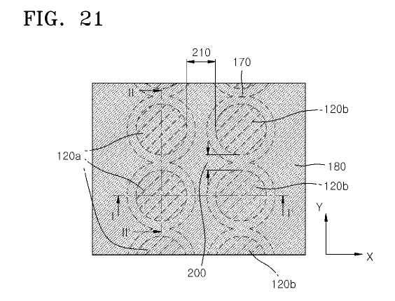

The semiconductor device formed through the above processes includes the semiconductor substrate 100, first contact patterns 120a, second contact patterns 120b, the bit line (150, refer to FIG. 20), the air gap 170, and the etch stop layer 180 as illustrated in FIG. 21. The first contact patterns 120a are arranged in one direction of the semiconductor substrate while being spaced apart from each other by a first distance 200. The second contact patterns 120b are arranged in parallel to the first contact patterns 120a while being spaced apart from the first contact patterns 120a by a second distance 210 longer than the first distance 200. The bit line 150 surrounds a part of the sidewalls of the first contact patterns 120a or the second contact patterns 120b while extending across between the first contact patterns 120a and the second contact patterns 120b, which are spaced apart from each other by the second distance 210. The air gap 170 is arranged between the first contact patterns 120a or the second contact patterns 120b and the bit line 150. The etch stop layer 180 is formed on the first and second contact patterns 120a and 120b, the bit line 150, and the air gap 170.

The bit line 150 is formed below the upper surfaces of the first contact patterns 120a or the second contact patterns 120b, and the capping insulation layer 160 is formed on the bit line 150, so that the bit line 150 is level with the upper surfaces of the first contact patterns 120a or the second contact patterns 120b.

According to an embodiment of the present invention, the contact patterns are first formed, and the bit line is formed after a formation position of the bit line is designated in advance, so that it is possible to reduce the process steps. Furthermore, the contact patterns are arranged while being spaced apart from each other by spaces where an insulation material is to be filled, and the insulation material is filled in the spaces to separate the spaces from each other, so that it is possible to form a bit line formation area without using a mask pattern. In addition, the thickness of the spacer formed at the sidewalls of the contact patterns is adjusted to control the line width of the bit line, so that it is possible to improve the uniformity of the line width of the bit line, as compared with the case where the bit line is formed using an etch process.

In an embodiment of the present invention, a process is performed to expose a part of the side of the spacer 130a by etching back the bit line 150. However, the present invention is not limited thereto. For example, the etch back process may not be performed according to an overlap margin between the contact pattern 120 and the storage node electrode to be connected to the contact pattern 120. For example, when the overlap margin between the contact pattern 120 and the storage node electrode is set to be larger than a limit range, it is possible to omit the etch back process. As described above, when the overlap margin is set to be larger than the limit range, a material constituting the bit line may be substantially the same as a material constituting the contact pattern 120.

According to an embodiment of the present invention, the distance between the storage node contacts is formed to the extent that an insulation material is filled therebetween, and the storage node contacts are separated from each other by the insulation material, so that it is possible to form the bit line without using a mask pattern. Furthermore, the storage node contacts are first formed, and the bit line is formed after a formation position of the bit line is designated in advance, so that it is possible to reduce the process steps.

In addition, the line width of the bit line is controlled by adjusting the thickness of the spacer formed at the sidewalls of the storage node contact, so that it is possible to improve the uniformity of the line width of the bit line.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method for fabricating a semiconductor device, the method comprising:
forming an interlayer dielectric layer including contact holes on a semiconductor substrate;
forming contact patterns by filling the contact holes with a conductive material;
removing the interlayer dielectric layer to expose the contact patterns;
forming a spacer which has a first thickness and surrounds at least a portion of sidewalls of the contact patterns;
forming a bit line extending in one direction of the contact pattern provided with the spacer; and
removing the spacer to form an air gap in between the contact pattern and the bit line.

2. The method of claim 1, wherein the contact holes are arranged in a row in a first direction of the semiconductor substrate while being spaced apart from each other by a first space, and are arranged in a second direction intersecting the first direction of the semiconductor substrate while being spaced apart from each other by a second space narrower than the first space.

3. The method of claim 2, wherein the first space is formed to have a width which is wider than a sum of a width of the bit line and a width of the spacer with a first thickness, and the second space is formed to have a width which is equal to or smaller than the width of the spacer which has a first thickness and surrounds at least a portion of the sidewalls of the contact patterns arranged in the second direction of the semiconductor substrate.

4. The method of claim 1, wherein the contact pattern includes a material having etching selectivity different from etching selectivity of a material constituting the interlayer dielectric layer.

5. The method of claim 1, wherein the interlayer dielectric layer is removed using a wet etch solution including a buffered oxide etchant (BOE) solution or a HF solution through a dip out process.

6. The method of claim 1, wherein the spacer includes a material having etching selectivity different from etching selectivity of a material constituting the contact pattern.

7. The method of claim 1, wherein the spacer fills the second space between the contact patterns arranged in a first direction of the semiconductor substrate.

8. The method of claim 1, wherein the bit line surrounds at least ⅓ of the sidewalls of the contact patterns.

9. The method of claim 1, further, after the forming of the bit line, comprising:
recessing the bit line by a first thickness from a surface of the bit line, thereby exposing a part of the spacer surrounding the contact pattern; and
forming a nitride layer covering the bit line by the recessed first thickness.

10. The method of claim 1, further, after the forming of the air gap, comprising:
forming an etch stop layer including a nitride layer on the contact patterns, the bit line, and the air gap.

11. The method of claim 10, wherein the etch stop layer is formed only in an inlet of the air gap.

12. The method of claim 1, wherein the spacer is removed using a wet etch solution including a buffered oxide etchant (BOE) solution or a HF solution.

13. A method for fabricating a semiconductor device, the method comprising:
forming an interlayer dielectric layer on a semiconductor substrate, which includes contact holes arranged in a first direction of the semiconductor substrate while being spaced apart from each other by a first space, and arranged in a second direction intersecting the first direction of the semiconductor substrate while being spaced apart from each other by a second space narrower than the first space;
forming contact patterns by filling the contact holes with a conductive material;
removing the interlayer dielectric layer to expose the contact patterns;
forming spacers which surround at least a portion of sidewalls of the contact patterns and fill the second space in the second direction;
forming bit lines extending across in a row between the spacers;
removing the spacer to form an air gap in between the contact pattern and the bit line; and
forming an etch stop layer on the contact patterns, the bit line, and the air gap.

14. The method of claim 13, wherein the first space is formed to have a width which is wider than a sum of a width of the bit line and a width of the spacer with a first thickness, and the second space is formed to have a width which is equal to or smaller than the width of the spacer which has a first thickness and surrounds at least a portion of the sidewalls of the contact patterns arranged in the second direction of the semiconductor substrate.

15. The method of claim 13, wherein the spacer fills the second space between the contact patterns arranged in the first direction of the semiconductor substrate.

16. The method of claim 13, wherein the bit line surrounds at least ⅓ of the sidewalls of the contact patterns.

17. A semiconductor device comprising:
a semiconductor substrate;
first contact patterns arranged in one direction of the semiconductor substrate while being spaced apart from each other by a first distance;
second contact patterns arranged in parallel to the first contact patterns while being spaced apart from the first contact patterns by a second distance longer than the first distance;
a bit line surrounds a part of the sidewalls of the first contact patterns or the second contact patterns while going across between the first contact patterns and the second contact patterns, which are spaced apart from each other by the second distance;
an air gap arranged between the first contact patterns or the second contact patterns and the bit line; and
an etch stop layer formed on the contact patterns, the bit line, and the air gap.

18. The semiconductor device of claim 17, wherein the bit line is formed below upper surfaces of the first contact patterns or the second contact patterns.

19. The semiconductor device of claim 17, further comprising:
a capping insulation layer that allows the bit line to be level with upper surfaces of the first contact patterns or the second contact patterns.

20. The semiconductor device of claim 17, wherein the bit line surrounds at least ⅓ of the sidewalls of the first contact patterns or the second contact patterns.
